(19) United States
(12) Patent Application Publication
(10) Pub. No.: US 2009/0194147 A1
(43) Pub. Date: Aug. 6, 2009

(54) DUAL SEAL PHOTOVOLTAIC ASSEMBLY AND METHOD

(75) Inventors: ROBERT C. GROMMESH, St. Louis Park, MN (US); RICHARD A. PALMER, Delano, MN (US); BENJAMIN J. ZURN, Roseville, MN (US)

Correspondence Address: INTELLECTUAL PROPERTY GROUP;FREDRIKSON & BYRON, P.A., 200 SOUTH SIXTH STREET, SUITE 4000, MINNEAPOLIS, MN, 55402, US

(73) Assignee: CARDINAL IG COMPANY, Eden Prairie, MN (US)

(21) Appl. No.: 12/337,853

(22) Filed: Dec. 18, 2008

Related U.S. Application Data
(63) Continuation-in-part of application No. 12/180,018, filed on Jul. 25, 2008.
(60) Provisional application No. 61/025,422, filed on Feb. 1, 2008.

(51) Int. Cl. H01L 31/048; B32B 37/00

(52) U.S. Cl. 136/251; 156/329

(57) ABSTRACT

A photovoltaic assembly including first and second substrates joined together and spaced apart, on either side of an airspace, by a seal system formed of a first seal and a second seal, the second seal comprising one or more silyl terminated polyacrylate polymers. A photovoltaic functional coating is disposed over a second major surface of one of the substrates, which faces the second major surface of the other substrate. Lead wires are coupled to bus bars and/or electrical contacts affixed to the functional coating and routed out from the airspace. Affixing the seal system to the first and second substrates, in order to join the substrates together, may be accomplished by applying pressure to the substrates.

### PRIORITY CLAIM

This application is a continuation-in-part of U.S. utility application Ser. No. 12/180,018, filed on Jul. 25, 2008, which claims priority to provisional application No. 61/025,422 filed on Feb. 1, 2008, the contents of both are incorporated herein by reference.

### TECHNICAL FIELD

The present invention pertains to photovoltaic assemblies and more particularly to photovoltaic assemblies that include at least two substrates spaced apart from one another on either side of an airspace. Such assemblies in the solar cell industry may be more commonly known or referred to as solar or photovoltaic modules or assemblies.

### BACKGROUND

Photovoltaic or solar cell devices or assemblies are used to convert light or solar energy into electrical energy. There are a variety of photovoltaic or solar cell devices but they generally fall into two basic categories or types, either bulk or thin film.

Bulk photovoltaic devices and bulk technologies are often referred to as “wafer-based.” Typically, self-supporting wafers between 180 to 350 micrometers thick are processed and then joined together to form a solar cell module. The most commonly used bulk material is silicon, more specifically crystalline silicon (abbreviates as “c-Si”). The various materials, methods of assembly and the like for formation of conventional bulk photovoltaic devices or assemblies are well-documented and known to those skilled in the art.

Thin film photovoltaic devices and thin film technologies have generally been developed with goals of reducing the amount of light-absorbing material required to create the solar cell or reducing overall size of the devices and assemblies. More recently, attention is increasingly being focused on enhancing the efficiency in the conversion of light to electrical energy. Ultimately, improvements in these areas can result in processing cost reductions compared to the costs for bulk solar cells devices.

Examples of materials that may be used in the manufacture of thin film photovoltaic devices include cadmium sulfide, cadmium telluride, copper-indium selenide, copper indium/gallium diselenide, gallium arsenide, organic semiconductors (such as polymers and small-molecule compounds like polyphenylene vinylene, copper phthalocyanine, and carbon fullerenes) and thin film silicon (typically deposited by chemical vapor deposition).

Thin film photovoltaic assemblies are conventionally manufactured by depositing thin film coatings or layers onto a substrate, such as glass, plastic or metal. Once the thin films are deposited they are generally sandwiched between a second substrate, typically of similar material and often referred to as a “backskin.” Another conventional solar cell configuration includes a polymeric encapsulant, such as polyethyl vinyl acetate (EVA), between the thin film coating and the second substrate or backskin. In other configurations, the polymeric encapsulant serves as the backskin. Similar encapsulation materials are known to be used in bulk devices and assemblies.

Glazing assemblies may include a pair of panels, or substrates, joined together such that a major surface of one of the substrates faces a major surface of the other substrates. At least one of the substrates of this type of assembly is transparent, or light transmitting, and may bear a coating on the major surface that faces the major surface of the other substrate. One example of such an assembly is an insulating glass (IG) unit, wherein the inner, or facing surface of one of the substrates bears a low emissivity coating. Such assemblies typically include a spacer and a sealant system and has an airspace typically filled with an inert gas or an airspace under vacuum. While a variety of sealant systems can be used, sealant system including a first seal of polyisobutylene and a second seal of silicone have been frequently used due to its superior performance. Often, the spacer is a hollow tubular member that is packed with a desiccant material. In some prior art assemblies, the seals were provided as strips and in others desiccant materials were embedded in the material forming the first and/or second seals.

Cardinal IG Company (Cardinal), assignee of the present application, manufactures IG units and has had a history of producing such units with industry leading weathering and durability performance for their IG units incorporating desiccated spacers and PIB and silicone sealant systems. With a projected 0.5% seal failure rate over twenty years, Cardinal has been able to provide 20-year warranties against seal failures that could lead to moisture intrusion that can damage the low emissivity coatings, cause fogging within the unit, and, if severe enough, corrosion of the glass.

Seal failures and moisture intrusion can also be a problem with conventional photovoltaic assemblies that employ lamination or polymeric encapsulation to protect photovoltaic coatings, lead wiring and the like. Photovoltaic assemblies for photovoltaic application, when configured as IG unit-type assemblies, may be more cost effective than traditional laminated solar panels, for example, in that a bulk of the material (e.g. EVA), which encapsulates the photovoltaic coating, in the traditional solar panel, is replaced with an air space, thereby reducing material cost and manufacturing time, per unit. Yet, there is still a need for improved configurations of photovoltaic assemblies that effectively incorporate photovoltaic coatings, in order to generate solar power. Thus, it would be desirable to provide an alternative photovoltaic assembly for photovoltaic applications with sealing systems that may also exhibit low seal failure rates. Rates approaching those seen with some IG units would be particularly desirable.

Furthermore, although silicone provides an excellent seal, it is known that the use of silicone in manufacturing can be associated with the release of volatile silicone compounds. These volatile silicone compounds could potentially interfere with electronic circuitry in solar cells or with adhesion, such as the adhesion of the semiconductor coating to the glass substrate, the adhesion of the bus bar tape and the adhesion of the back-box. These problems may also be associated with the use of silicone in potting materials. Therefore, it is desirable to provide an alternative seal and/or potting material for solar cells which does not release volatile silicone compounds.

### SUMMARY OF THE INVENTION

In one embodiment in accordance with the present invention, a photovoltaic assembly is provided. The assembly has a first substrate and a second substrate. The first substrate is formed of a transparent or light transmitting material. Each of the first and second substrates have first and second major surfaces and each second surface has a central region and a periphery. The second surfaces of the substrates face one another and are spaced apart from one another. The assembly further includes a photovoltaic coating disposed over at least the central region of the second surface of the first substrate and a seal system comprised of a first seal and a second seal. The seal system is disposed between the first and second substrates, joining the first and second substrates to one another, along their peripheries. The second seal comprises a silyl-containing polyacrylate polymer. The seal system encloses an airspace that extends between the second surfaces of the first and second substrates and along the central regions thereof.

In some embodiments of the invention, the first seal is formed of an extrudable material that results in a moisture vapor transmission rate therethrough, which does not exceed approximately 10 g mm/m²/day when measured according to ASTM F 1249 at 38° C. and 100% relative humidity. In other embodiments of the invention, the first seal is formed of a desiccant-free polymeric material. In yet other embodiments, the first seal is comprised of a butyl sealant material. In other embodiments, the first seal comprises a polymeric material and a dessicant. In some embodiments, the photovoltaic assembly includes a spacer and in other embodiments there is no spacer.

Further, in other embodiments according to the invention one or more openings may be provided, the one or more openings extending through the seal system or from the first surface to the second surface of either the first substrate or the second substrate. In some embodiments, the photovoltaic coating is disposed over both the central region and the periphery of the second surface of the first substrate.

In some embodiments of the invention, the seal system extends over the periphery of the second surface of the first substrate. In other embodiments, the seal system further extends over an edge portion of the photovoltaic coating, the edge portion being located adjacent to the periphery of the second surface of the first substrate.

In another embodiment of the invention, the assembly further includes a desiccant material disposed within the air space. In yet another embodiment of the invention, the assembly further comprises one or more seal members which are disposed within the airspace, which at least partially surround or border an opening through one of the substrates. Additionally, in some embodiments of the invention, the assembly may include one or more support members.

In another embodiment of the invention, a method for making a photovoltaic assembly is provided. The method includes the steps of forming a first substrate and a second substrate, the first and second substrates having first and second major surfaces, each of the second surfaces having a central region and a periphery, and at least the first substrate being transparent; forming a photovoltaic coating over at least the central region of the second surface of the first substrate or the second substrate; providing a seal system comprising a first seal and a second seal, the second seal comprising a silyl-containing polyacrylate polymer; applying the first seal to the periphery of at least one of the substrates; bringing the first and second substrates together in opposed relationship with the first seal disposed along the peripheries thereof, such that an airspace is formed between the second surfaces and along the central regions thereof; applying pressure to the assembly to join the first and second substrates together such that the airspace is maintained between the first and second substrates.

In yet another embodiment according to the invention, a method for making a photovoltaic assembly is provided. The method includes the steps of providing a first substrate and a second substrate, the first and second substrates having first and second major surfaces, each of the second surfaces having a central region and a periphery, at least the first substrate being transparent and at least one of the substrates bearing a photovoltaic coating disposed over at least the central region of the second major surface; providing a seal system comprising a first seal and a second seal, the second seal comprising a silyl-containing polyacrylate polymer; applying the first seal to the periphery of at least one of the substrates; bringing the first and second substrates together in opposed relationship with the first seal disposed along the peripheries thereof, such that an airspace is formed between the second surfaces and along the central regions thereof; and applying pressure to the assembly to join the first and second substrates together such that the airspace is maintained between the first and second substrates.

In either of the foregoing embodiments of a method according to the invention, the method may further include the step of applying a second seal over the first seal. In other embodiments according to the invention, the applying step may further include depositing the first and second seals serially or simultaneously, prior to bringing the first and second substrates together. In yet other embodiments according to the invention, the method may further include one or more of the following additional steps of forming at least one opening through the seal system or through the second substrate, the opening extending from the first to the second surface thereof and being located in the central region of the second surface; sealing the opening; providing a contact layer and/or bus bars affixed to the photovoltaic coating; providing at least one support member or a desiccant in the airspace.

### BRIEF DESCRIPTION OF THE DRAWINGS

The following drawings are illustrative of particular embodiments of the present invention and therefore do not limit the scope of the invention. The drawings are not to scale (unless so stated) and are intended for use in conjunction with the explanations in the following detailed description. Embodiments of the present invention will hereinafter be described in conjunction with the appended drawings, wherein like numerals denote like elements.

FIG. 1 is a perspective view of a photovoltaic assembly, according to some embodiments of the present invention.

FIG. 2 is a schematic plan view of either of the substrates of the assembly shown in FIG. 1.

FIG. 3 is a perspective view of a portion of the assembly shown in FIG. 1, according to some embodiments of the present invention.

FIGS. 4-6 are section views through line A-A of FIG. 1, according to various embodiments of the present invention.

FIG. 7A is a cross-section of a portion of a coated substrate of any of the assemblies shown in FIGS. 4-6.

FIG. 7B is a perspective view of a portion of any of the assemblies shown in FIGS. 4-6, according to some further embodiments.

FIG. 8A-8D are perspective views of a portion of the assembly shown in FIG. 1, according to some embodiments of the present invention.

FIG. 9A-9D are perspective views of a portion of the assembly shown in FIG. 1, according to some embodiments of the present invention.

FIG. 10 is a section view of a partially formed assembly according to some embodiments of the present invention.

FIG. 11 is a partial section view of an assembly according to some embodiments of the present invention.

FIG. 12 is a partial section view of an assembly according to some embodiments of the present invention.

FIG. 13 is a partial section view of an assembly according to some embodiments of the present invention.

### DETAILED DESCRIPTION

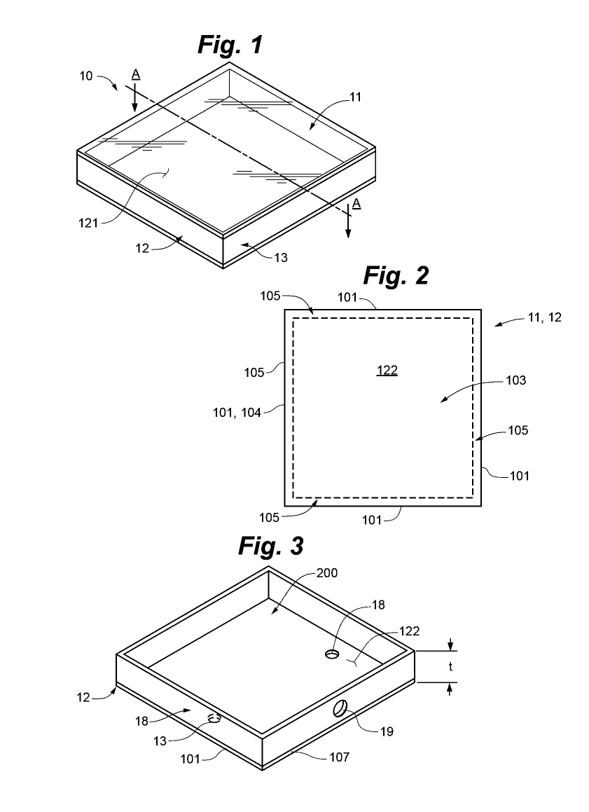

The following detailed description and FIGS. 1-11 are exemplary in nature and are not intended to limit the scope, applicability, or configuration of the invention in any way. Rather, the following description and the figures provide practical illustrations for implementing exemplary embodiments of the present invention.

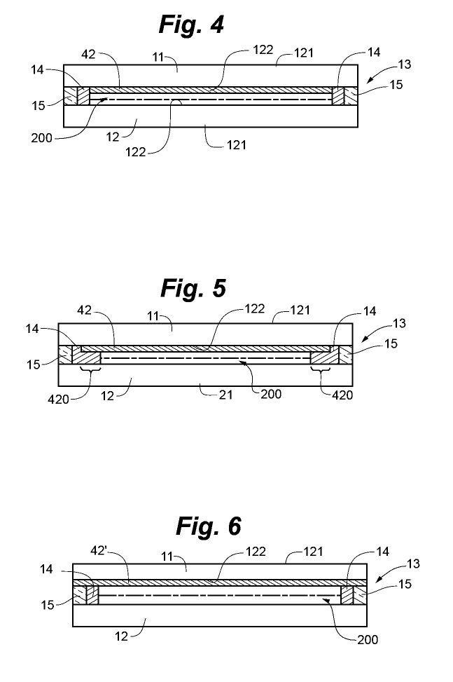

FIG. 1 is a perspective view of a photovoltaic assembly 10, according to some embodiments of the present invention. FIG. 1 illustrates assembly 10 including a first panel, or substrate 11, a second panel, or substrate 12 and a sealing system 13 which is disposed between first substrate 11 and second substrate 12 and which joins substrates 11, 12 together; a first major surface 121 of each of substrates 11, 12, face outward or away from one another, and a second major surface 122 of each of substrates 11, 12 faces inward, or toward one another, being spaced apart from one another by seal system 13. First and second surfaces 121, 122 of each substrate 11, 12 may be more clearly seen in the section views of FIGS. 4-6 and 9. Seal system 13 comprises a first seal 14 and a second seal 15. Seals 14, 15 can also be more clearly seen in FIGS. 4-6 and 9.

According to the illustrated embodiment, first substrate 11, second substrate 12 or both may be transparent, or light transmitting, for example, formed from glass or a plastic material, such as polycarbonate. Depending on which first surface 121 is exposed to the external environment, i.e., faces the source of light entering the assembly, the corresponding substrate would be formed of a transparent or light transmitting material. The opposed substrate may be similarly formed, according to some embodiments, but may be tinted, translucent, or opaque according to some alternate embodiments or may be provided with an opacifier layer. In other words, it need not have the same light transmitting properties or be formed of the same material. Thus, it should be understood that the embodiments of assembly 10 illustrated in FIGS. 4-9 may have reversed arrangements or orientations, in that, depending on which is the active side of photovoltaic coating 42 or which substrate bears photovoltaic coating 42, either first substrate 11 or second substrate 12 may be transparent and have its first surface 121 exposed to the external environment, i.e., facing the source of light. Phrased alternatively, in some embodiments of the invention such as those illustrated in FIGS. 4-6, if first surface 121 of first substrate 11 is facing the source of light and first substrate 11 bears photovoltaic coating 42 on its second surface 122, first substrate 11 is transparent and the opposite substrate, second substrate 12, is not required to be transparent. Similarly, with reference to FIGS. 4-6, if first surface 121 of second substrate 12 is facing the source of light and first substrate 11 bears photovoltaic coating 42 on its second surface 122, second substrate 12 is transparent and the opposite substrate, first substrate 11, is not required to be transparent.

Although the term “glazing” typically connotes incorporation of a glass panel or substrate, the use of the term is not so limited in the present disclosure, and photovoltaic assemblies of the present invention may incorporate any transparent, or light transmitting substrate, for example, formed from a plastic such as polycarbonate, for use as substrates, 11, 12. Further, while the embodiments illustrated in the figures are generally square or rectangular in shape, it should be understood that assemblies according to the invention are not limited to the illustrated shapes and, in fact, may be of any of a variety of desirable shapes, including, but not limited to, polygonal, circular, semi-circular, oblong and the like.

FIG. 2 is a schematic plan view of either of the substrates 11, 12 of assembly 10. FIG. 2 illustrates second major surface 122 of substrate 11/12 having edge or edges 101, a central region 103 and a periphery 105, which are delineated from one another by the dashed line. With reference to FIGS. 1 and 2, in conjunction with FIG. 3, which is a perspective view of assembly 10 having first substrate 11 removed, it may be appreciated that seal system 13 joins first substrate 11 to second substrate 12 along at least a portion of periphery 105 of each substrate. When substrates 11, 12 are of the same size or dimensions, they may be joined together with their peripheries 105 or edges 101 aligned. However, in some embodiments of assembly 10 of the invention, substrates 11, 12 may be joined together without their peripheries or edges being aligned. In such embodiments, this may be due to substrates 11, 12 not having the same dimensions and when joined together by seal system 13, their peripheries may only be partially overlapping and their edges not directly aligned due to the size differential, one substrate being undersized relative to the other. Thus, the phrase “along the periphery” or “along their peripheries” and similar references to the relationship between the peripheries of substrates 11, 12 should be understood to include the peripheries being in a partially overlapping relationship as well as the peripheries 105 and/or the edges 101 of the substrates being aligned.

FIG. 3 illustrates an airspace 200 that extends between second surfaces 122 of the joined substrates 11, 12. The term airspace, as used herein, is intended to encompass a space that is either filled with any type of gas, not only air, or that has a vacuum. In some embodiments of the invention, the airspace may be under vacuum or the gas may be under pressure. FIG. 3 further illustrates seal system 13 having a thickness t, corresponding approximately to the distance between the second surfaces 122 of joined substrates 11, 12. In embodiments of the present invention, thickness t may range between approximately 0.01 inch and approximately 1.5 inches. According to preferred embodiments of the present invention, thickness t is preferably between approximately 0.01 inch and approximately 1 inch. In alternate embodiments of the invention, thickness t is preferably between approximately 0.01 inch and approximately 0.5 inch. In other alternate embodiments of the invention, thickness t is preferably between approximately 0.01 inch and approximately 0.1 inch; and in yet others thickness t is between approximately 0.01 inch and approximately 0.04 inch.

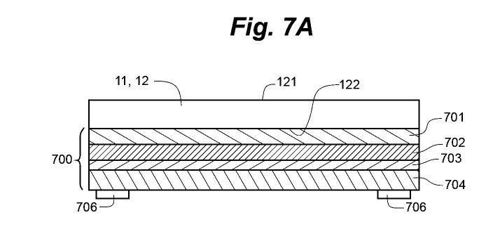

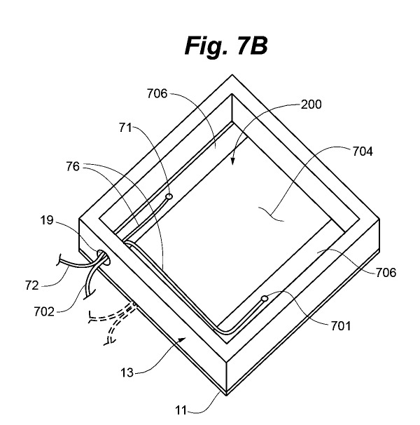

Optionally, one or more openings 18 may be formed in substrates 11, 12, for example, in second substrate 12 as shown in FIG. 3, depicting a pair of optional openings 18. Openings 18, may be used to equalize pressure within assembly 10 during manufacture or processing and/or to fill airspace 200 with another gas and/or to draw vacuum between joined substrates 11, 12, and/or to dispense a desiccant material into airspace 200, and/or to provide access for other secondary manufacturing operations that need to be performed within airspace 200, for example, those related to a photovoltaic functional coating 42 borne by a substrate, such as is described below with reference to an exemplary coating shown in FIG. 7A. Further, pre-formed seal opening 19 or grommets 19, as seen in FIG. 3 may also optionally be provided in addition to or instead of openings 18. Seal openings 19 may be utilized for similar purposes to openings 18.

According to preferred embodiments of the present invention, first seal 14 may be formed of an extrudable material such a as a polymeric adhesive material which more preferably is largely impermeable to moisture vapor and gases (e.g., air or any gas fill). In some preferred embodiments of the invention, first seal 14 is formed of an extrudable material having low moisture vapor transmission properties and more preferably an extrudable material resulting in a moisture vapor transmission rate (MVTR) therethrough, which does not exceed approximately 10 g mm/m²/day when measured according to ASTM F 1249 at 38° C. and 100% relative humidity. In some preferred embodiments of the invention, suitable first seal materials may have MVTR, when measured according to ASTM F 1249 at 38° C and 100% relative humidity, that does not exceed approximately 5 g mm/m²/day, and more preferably does not exceed approximately 1 g mm/m²/day. It is an additionally desirable property that materials used for first seal 14 have excellent adhesion properties. Examples of suitable materials include both non-setting materials and setting materials, e.g., cross-linking, and may include thermoplastic, thermosetting and air, moisture or UV curable materials. In some preferred embodiments first seal 14 is comprised of a butyl sealant, such as polyisobutylene or butyl rubber. Materials suitable for use as first seal 14 preferably having low conductivity or electro conductivity. The applicable international test standard for low conductivity is the IEC 61646 International Standard for Thin-Film Terrestrial Photovoltaic (PV) Modules—Design Qualification and Type Approval (“IEC 61646 Standard”). Materials particularly suited for use in embodiments of the invention are those that meet the IEC 61646 Standard. Those skilled in the art can readily identify materials suitable for use as first seal 14 that exhibit desired adhesive properties and/or MVTR and/or low electro conductivity. In some embodiments of the invention, first seal 14 is “desiccant free”, meaning that it is applied without desiccant embedded or mixed in the sealant materials forming first seal 14. Non-limiting, commercially available examples of materials that may be used as first seal 14 and exhibit one or more of the above-described desirable properties, e.g., low MVTR or low conductivity include but are not limited to Adcotherm™ sealants such as PIB 7-HS, PIB 8-HS and PIB 29 available from ADCO Products Inc. In some embodiments, the first seal 14 includes a desiccant, such as a desiccant embedded or mixed in the sealant material forming the first seal. For example, the first seal 14 may comprise a thermoplastic material mixed with a drying agent. An example of a seal including a desiccant is disclosed in U.S. Pat. No. 6,673,997. Commercially available materials that may be used in the first seal 14 which may include a desiccant include, for example, HelioSeal™ PVS-110 and Kodimelt TPS, both available from ADCO Products, Inc. of Michigan Center, Mich.

In some embodiments, the second seal is comprised of a composition comprising one or more silyl containing polyacrylate polymers. For example, the second seal may comprise a silyl terminated polyacrylate polymer. In some embodiments, the silyl terminated polyacrylate polymer has an average of at least 1.2 alkoxysilyl chain terminations per molecule. For example, the silyl terminated polyacrylate polymer may be described by the following average formula:

SiR¹ₓ(OR)₃₋ₓ

where R is methyl, ethyl, n-propyl, or isopropyl, R1 is methyl or ethyl, and x is 0 or 1. The composition may further comprise a catalyst. In some embodiments, the catalyst is a metal catalyst such as a tin or a titanium catalyst. In some embodiments, the catalyst is a carboxylic acid metal salt. Examples of carboxylic acid metal salts which may be used include calcium carboxylate, vanadium carboxylate, iron carboxylate, titanium carboxylate, potassium carboxylate, barium carboxylate, manganese carboxylate, nickel carboxylate, cobalt carboxylate and zirconium carboxylate. Examples of carboxylic acids useful in embodiments of the invention are disclosed in U.S. Pat. No. 7,115,695 to Okamoto et al., the relevant portions of which are hereby incorporated by reference.

In various embodiments, another example of silyl containing polyacrylate polymer useful as the second seal is formed of a silyl terminated acrylic polymer such as XMAP™ polymer, available from Kaneka Corporation (Osaka, Japan). The second seal may be formed from XMAP™ polymer alone or in combination with one or more other polymers.

In addition, the composition of the second seal may comprise fillers, such as calcium carbonate, silica, clays, or other fillers known in the art. The second seal may also include a variety of other additives including, but not limited to, crosslinkers, plasticizers, thixotropic agents, UV absorbers, light stabilizers, dehydration agents, adhesion promoters, catalysts, titanium dioxide, ground and/or precipitated calcium carbonate, talc and other suitable additives.

The silyl terminated polyacrylate polymers, such as XMAP™ polymers, may be used in the second seal to provide a strong and weather resistant adhesive. Unlike conventional silicone sealants, XMAP™ polymer lacks volatile cyclic silicone compounds and releases only very low levels of volatile non-cyclic silicone compounds. The use of XMAP™ polymer in the second seal may therefore reduce the risk of potential problems due to volatile cyclic silicone compounds, such as interference with electronic circuitry of the solar cells or interference with the adherence of the semiconductor coating to the glass substrate, adherence of acrylic adhesive such as the bus bar tape.

The XMAP™ polymer is represented by the formula:

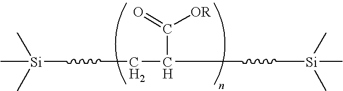

R may be a hydrocarbon group with one free bond for attachment or a hydrocarbon group with one available bonding site. In some embodiments, R is a butyl or an ethyl group. Nonlimiting examples of R functional groups include but are not limited to methyl, ethyl, n-propyl, isopropyl, n-butyl, isobutyl, tert-butyl, n-pentyl, n-hexyl, cyclohexyl, n-heptyl, n-octyl, 2-ethylhexyl, nonyl, decyl, dodecyl, phenyl, tolyl, benzyl, 2-methoxyethyl, 3-methoxybutyl, 2-hydroxylethyl, 2-hydroxylpropyl, stearyl, glycidyl, 2-aminoethyl, gamma-(methacryloyloxypropyl)trimethoxysilane, ethylene oxide adduct of (meth)acrylic acid, trifluoromethylmethyl, 2-trifluoromethylethyl, 2-perfluoroethylethyl, 2-perfluoroethyl-2-perfluorobutylethyl, 2-perfluoroethyl, trifluoromethyl, bis(trifluoromethly)methyl, 2-trifluoromethyl-2-perfluoroethylethyl, 2-perfluorohexylethyl, 2-perfluorodecylethyl and 2-perfluorohexadecylethyl. Examples of monomers which may be used in the invention are described in U.S. Patent Publication Number 2006,0252903, the relevant portions of which are hereby incorporated by reference. The molecular weight may be between approximately 500 and 100,000, and n may be between approximately 3 and approximately 100,000. For some embodiments, n may preferably be 50 or more; and in other embodiments n maybe 100 or more. For yet some other embodiments, n is preferably at least 200, and more preferably at least 400. XMAP™ polymers as used in the second seal may have low polydispersity (PDI) ranging from about 1.1 to about 1.6. They can be prepared with a molecular weight variety and have high end-functionality. A variety of polymer backbones may be used, i.e., a variety of homopolymers and copolymers of various acrylates. The polymer backbones typically have only carbon-carbon single bonds. The polymer also has carbon-silicon bonds at the telechelic ends and ester groups throughout the backbone. XMAP™ polymers can be liquid at room temperature. XMAP™ polymers can have a weathering resistance which is comparable to silicone sealants and may be resistant to heat at temperatures up to 300° F. In addition, they can be oil resistant.

XMAP™ polymers can cure through various routes, including condensation, addition, or radical curing processes. They may be produced using living radical polymerization technology, as shown below:

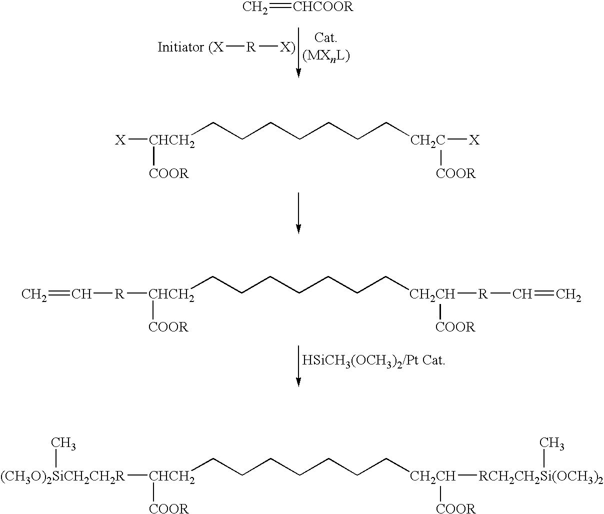

Embodiments of the present invention further include a photovoltaic coating extending over at least the central region or both the periphery and central region of major surface 122 of one of substrates 11/12. According to some preferred embodiments, second major surface 122 of first substrate 11 bears a photovoltaic coating. The extent of a coating borne by second surface 122 of first substrate 11, with respect to an extent of seal system 13, may vary according to various embodiments, examples of which are illustrated in FIGS. 4-6. First seal 14 formed, for example, of a polyisobutylene sealant will adequately adhere to both the native second surfaces 122 of substrates 11, 12 and to materials forming the photovoltaic coating over surface 122, in order to join first and second substrates 11, 12 together for the various embodiments described below in conjunction with FIGS. 4-6. Further, in some embodiments of the invention, first seal 14 will also adhere to bus bars and other electric contacts affixed to coating 42. In such embodiments, first seal may provide adhesive support to any adhesives or welding helping to secure bus bars and/or electric contacts and/or lead wires to one another and/or to coating 42.

FIGS. 4-6 are section views through line A-A of FIG. 1, according to various embodiments of the present invention. Although FIGS. 4-6 are shown without a spacer, each embodiment could optionally include a spacer. FIG. 4 illustrates a coating 42 disposed over only central portion 103 (FIG. 2) of second surface 122 of substrate 11, and seal system 13 extending over only periphery 105 (FIG. 2) of second surface 122. FIG. 5 illustrates an alternate embodiment wherein seal system 13 further extends over a portion of central region 103, and over an edge portion 420 of coating 42, which edge portion 420 is located adjacent to periphery 105. FIG. 6 illustrates another alternate embodiment, wherein coating 42′ is disposed over both central region 103 and periphery 105, of second surface 122 of substrate 11, so that seal system 13 extends over a portion of coating 42′.

A dashed line in each of FIGS. 4-6 schematically represents an optional desiccant material enclosed within airspace 200 to absorb any moisture that may pass through seal system 13 or that is present after assembly. Desiccant material may be provided in a variety of forms, including but not limited to wafer forms, sheet or strip form, or granular form or packaged in a sack or bag, may be ‘free-floating’ in airspace 200, or adhered to one of substrates 11, 12, or otherwise present in airspace 200, or may be in the form of commercially available desiccant-containing polymeric matrix material. Preferred desiccant materials are of the type commonly referred to by those skilled in the art as molecular sieves.

Desiccant wafers are commercially available from, for example, Sud-Chemie of Bellen, N.M., for custom applications. Desiccant in granular form is commercially available from, for example, Zeochem, Louisville Ky., a manufacturer of molecular sieves. Molecular sieves are a preferred desiccant material because of their superior moisture retention at elevated temperature as compare to silica gels.

Desiccant sheets and strips can be readily prepared by applying an adhesive to a sheet material or providing an adhesive sheet material and then applying and adhering desiccant in granular form to the adhesive. The adhesive may be applied over the entire surface of the sheet material or only over a central region. During preparation, adhesive may first be applied to the central region of the sheet material, followed by application of desiccant granules or beads. The desiccant sheets may be provided with the granules deposited over the entire surface or only over the central region and with a release material over the granules and both the periphery and the central region. Preferably, the sheet material is additionally provided with a release material or sheet over the adhesive and the release sheet is perforated or scored so that a central portion can be removed; and then a desiccant is applied to the central region of the sheet material. For ease in manufacturing of assemblies, when preparing desiccant sheets, granules will typically be adhered to the central region of the sheet material only so that the periphery will be available upon removal of the release material to secure the desiccant sheet without need for additional adhesives or tapes. Suitable materials for the sheet material include those that allow moisture to pass through or into them in order to be absorbed by the desiccant. A release material over the desiccant granules may help prevent their removal by mechanical forces during handling, shipping and/or storage.

Desiccant containing bags can also be readily prepared but are generally commercially available from, for example, Sud-Chemie of Bellen, N.M. Examples of commercially available desiccated polymeric matrix materials that are available include, but are not limited to, WA 4200, HA 4300, H9488J desiccated matrices from Bostik of Wauwatose, Wis. and HL5157 desiccated matrix from HB Fuller Company of St. Paul, Minn.

According to preferred embodiments of the present invention, the aforementioned desiccant material, which is enclosed within airspace 200, in combination with the aforementioned relatively low MVTR of first seal 14 of seal system 13, effectively prevents moisture build-up within airspace 200 that can lead to corrosion of certain elements of the photovoltaic coating or electrical connections or contacts. The incorporation of airspace 200 in combination with the desiccant material, rather than having the material of seal system 13 extend, as an encapsulant, between all of coating 42, 42′ and second surface 122 of second substrate 12, may significantly reduce the amount of moisture that could come in contact with coating 42 within assembly 10.

According to some embodiments of the present invention, coating 42 or 42′ may be a bulk photovoltaic coating or a thin film photovoltaic coating. It is contemplated and should be understood that such coatings may be of any type known to those skilled in the art to be useful as a photovoltaic coating.

FIG. 7A is a cross-section of substrate 11 bearing an exemplary photovoltaic coating 700 over second surface 122. In this case, FIG. 7A illustrates coating 700 of the thin film variety including from substrate 11, 12 outward a first layer 701 formed of a transparent conductive oxide (TCO), for example, comprising tin oxide, a semiconductor layer 702, for example, comprising two ‘sub-layers’: Cadmium sulfide (‘window’ layer; n-type), extending over layer 701, and Cadmium Telluride (absorbing layer; p-type), extending over the Cadmium sulfide. FIG. 7A further illustrates an electrical contact layer 703, for example, comprising nickel, sandwiched between the Cadmium Telluride of semiconductor layer 702 and a contact layer 704 and bus bar 706, to which bus bar 706 electrical lead wires may be coupled for collection of electrical energy generated by a photovoltaic coating 700 in some embodiments of assembly 10 according to the invention. The lead wires may be routed out from between substrates 11, 12 through openings 18 and/or or seal opening 19 (FIG. 3), or out through seal system 13, for example, as is illustrated in FIG. 7B.

FIG. 7B is a perspective view of a portion of a photovoltaic assembly, for example, similar to assembly 10 of FIG. 1, wherein lead wires 76 extend through seal opening 19 in seal system 13 or between seal system 13 and second surface 122 of substrate 11. FIG. 7B illustrates each of lead wires 76 including an inner terminal end 71, 701 coupled to bus bar 706 of coating 700, within airspace 200, and each of lead wires 76 including an outer terminal end 72, 702, accessible outside of airspace 200. According to the illustrated embodiment, inner terminal ends 71, 701 may be coupled to bus bar 706 of coating 700, prior to affixing first and second substrates 11, 12 together with seal system 13, and then outer terminal ends 72, 702 may be coupled to power transmission system, power collection or storage system or a load upon installation of the completed photovoltaic assembly. Thus, opening(s) 18 (FIG. 3) are not required for embodiments of photovoltaic assemblies that include the wire routing illustrated in FIG. 7B, nor for yet another wire routing embodiment in which the lead wires are passed out from airspace 200 between seal system 13 and first substrate 11, for example, as illustrated with dashed lines in FIG. 7B. While opening 18 may not be required when seal opening 19 is provided (or when the wiring in routed between second surface 122 and seal system 13), both may be provided in some embodiments of assemblies of the invention. Whether opening 18 or seal opening 19, it should be understood that lead wires may be routed for coupling to bus bar 706, after substrates 11, 12 are affixed to seal system 13; and that lead wires may be routed through opening 18 and/or seal opening 19 and/or between seal system 13 and second surface 122 of substrate 11, 12 as mentioned above. Whether used alone or in conjunction with at least one opening 18, seal opening 19 can serve or perform substantially the same purpose or function as opening 18, i.e., pressure equalization, filling airspace 200 with a gas, drawing a vacuum, dispensing or depositing a desiccant material into airspace 200, and/or providing access for manufacturing operations performed within airspace 200.

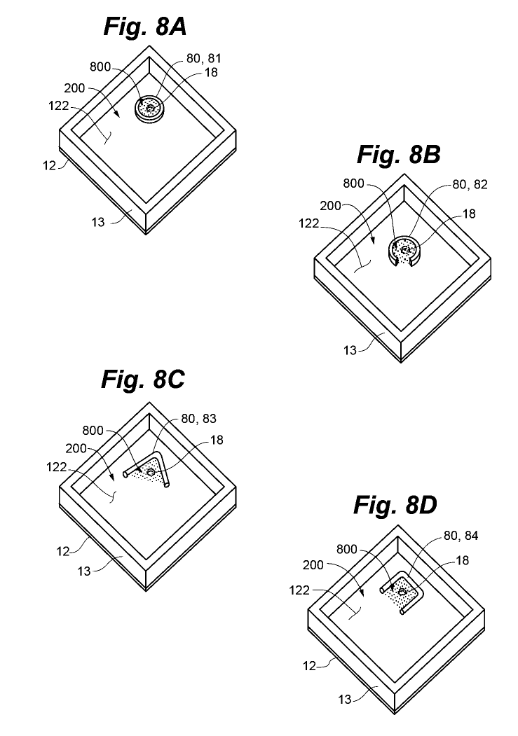

With reference to FIGS. 8A-D, assembly 10 according some embodiments of the invention may further include one or more seal members 80, that partially surround or border at least a portion of the perimeter of opening 18. In FIGS. 8A-D, exemplary seal members 80 are illustrated. Seal members 80 provide a partial back stop against or enclosure into which potting materials may be applied and deposited in order to seal opening 18. In certain embodiments, the potting material comprises a silyl containing polyacrylate polymer, e.g. a silyl terminated acrylic polymer such as a XMAP™ polymer, either alone or in combination with one or more other polymers. The seal members 80 contain a potting material 800 in a relatively fixed location within and/or around opening 18 until the material cures or sets. The seal members may be extruded, preformed, or otherwise applied as a deposit of a polymeric or other suitable material. In some embodiments of the invention in which the seal members 80 are applied or deposited around the perimeter of opening 18, any of the extrudable materials suitable for use for first seal 14 may be deposited as a seal member 80.

FIG. 8A illustrates the assembly including a circular shaped seal member 81, having a thickness, like seal system 13, to span airspace 200 between first substrate 11 and second substrate 12. FIG. 8A further illustrates seal member 81 completely surrounding the perimeter of opening 18 as a seal member. FIG. 8B illustrates the assembly including a C-shaped seal member 82, which also has a thickness, like seal system 13 and seal member 81 of FIG. 8A, to span airspace 200, but which partially surrounds the periphery of opening 18. FIG. 8C illustrates the assembly including a V-shaped seal member 83, also having a thickness, like seal system 13 and seal member 81 of FIG. 8A, to span airspace 200, but which partially surrounds the periphery of opening 18. FIG. 8D illustrates the assembly including a generally rectilinearly shaped seal member 84, partially surrounding the periphery of opening 18 and having a thickness, like seal system 13 and seal member 81, to span airspace 200. In some embodiments of the invention, seal members may be provided with a thickness that is less than that of seal system 13.

According to the illustrated embodiments, after opening 18 has provided necessary access within the airspace for performing a secondary operation related to manufacture of assembly 10, for example, any of the aforementioned operations, a potting material 800 is applied to seal off opening 18, and seal members 80 such as either of seal members 81, 82, 83, 84 provide a barrier or backstop to control the flow of potting material 800, and thereby limit an extent of material 800 over second surface 122 of either or both of substrates 11, 12. As previously described, opening 18 may further provide a passageway for routing lead wires from a photovoltaic coating that may extend over surface 122 of first substrate 11 or a bus bar in contact with the photovoltaic coating; according to these embodiments, potting material 800 is applied around the lead wires within opening 18.

Assembly 10 according some embodiments of the invention may further comprise one of more support members. Support members, when disposed in the airspace, can provide additional stability to the spacing between substrates 11, 12 during processing, shipping, and handling. Additionally, support members can help prevent collapse of the airspace or contact between the coating, contact layer or bus bar and the opposed substrate, particularly when assemblies are manufactured at high altitude and transported through or installed in lower altitude areas. Support members may also increase thermal transfer from the semiconductor or coating 42, 42′ to the uncoated glass and decrease temperature of assembly 10. A variety of materials may be used as support members. Suitable materials may be flexible or resilient and preferably have a durometer sufficient to withstand thermal expansion and/or contraction of the airspace. The support members may be extruded elements, preformed elements or applied as a deposit of a polymeric or other suitable material. Support members are preferably formed of a polymeric material.

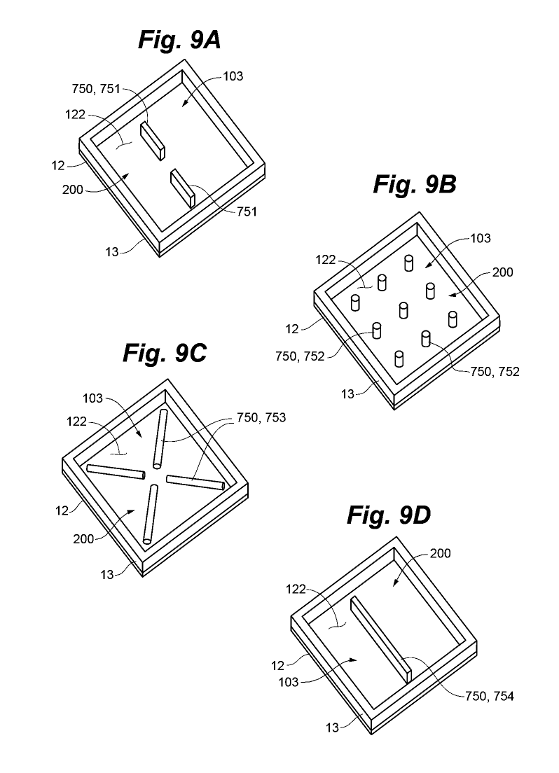

FIGS. 9A-D are perspective views of a portion of a photovoltaic assembly, for example, similar to assembly 10, shown in FIG. 1, wherein first substrate 11 is removed for clarity in illustration. Support members 750 illustrated in 9A-D are intended to be illustrative, non-limiting examples. As can be seen, support members 750 may be provided in any of a variety of shapes or configurations.

FIGS. 9A-D present some embodiments of the invention incorporating one or more support members 750, which provide additional stability to the spacing between substrates 11, 12. FIG. 9A illustrates a plurality of support members 751 each having a thickness, similar to seal system 13, to span airspace 200 between first and second substrates 11, 12; each support member 751 is shown extending over a portion of central region 103. FIG. 9B illustrates a plurality of support members 752, having a thickness, similar to seal system 13, to span airspace 200 between first and second substrates 11, 12; support member 752 is shown extending diagonally between opposing corners of seal system 13. FIG. 9C illustrates a plurality of support members 753 having a thickness, similar to seal system 13, to span airspace 200 between first and second substrates 11, 12; the plurality of support members 753 are shown located over central region 103. FIG. 9D illustrates a support member 754 having a thickness, similar to seal system 13, to span airspace 200 between first and second substrates 11, 12; the plurality of support member 754 is shown located centrally located over a portion of central region 103. Support members 750, 751, 752, 753, 754 may be formed from the same materials useful for support members 81, 82, as previously described.

In some embodiments of the invention, any of the extrudable materials suitable for use for first seal 14 may also be deposited as a support member 750. While support members 750 in any of their various configurations may have a thickness, similar to that of seal system 13, it should be understood that the support members may have a thickness less than that of the seal system 13 and may not span the entirety of airspace 200 between first and second substrates 11, 12 in all embodiments nor is a requirement of the invention that the support members do so. Further, still, it should be understood that when support members are being formed, for example when extruded or applied as a polymeric deposit, the support member may have a thickness greater than that of the seal system during some stages of assembly. Preferably, support members do not completely divide airspace 200 into multiple compartments; however, if support members are so applied, desiccant will need to be applied into each compartment, unless a means for fluid communications is provided between any such compartments. Also an opening 18 or seal opening 19 may need to be associated with each compartment if pressure equalization is required during assembly.

As previously mentioned, support members may be also be provided as a plurality of discrete deposits or a plurality of bumpers over major surface 122 (FIG. 9B) of either or both of first and second substrates 11/12. For example, referring to FIG. 9B, support members 752 are shown. The illustrated plurality of support members may be formed, for example, of discrete polymeric deposits or by extrusion of any of the extrudable materials suitable for use as first seal 14 or applied as pre-formed bumpers such as self-adhering bumpers available as 3M Bumpon™ bumpers or applied using other pre-formed materials such as Sentry Glas®Plus, available from DuPont, and PRIMACOR™, available from Dow Chemical. In some embodiments, the support members may additionally include a desiccant incorporated therein. Some polymeric materials used as support member, may require application of heat to secure and affix them in place.

Some methods for making photovoltaic assembly 10, as generally shown in FIG. 1, and according to any of the alternative embodiments described in conjunction with FIGS. 1-9D, will now be described. In an initial method step, a pair of panels, or substrates, for example substrates 11, 12, are formed according to methods well known in the art. Formation of one or both of the substrates may include a step of coating one or both major surfaces of the substrate. According to some preferred embodiments, the major surface of one of the substrates, which will face a major surface of the other substrate in the photovoltaic assembly, for example, second surface 122 of first substrate 11, is coated with either a low emissivity coating or a photovoltaic coating, according to methods known to those skilled in the art. The initial substrate formation step may further include a step of forming at least one opening through one or both of the substrates, preferably, the substrate which does not include the coating.

Some methods for making photovoltaic assembly 10, as generally shown in FIG. 1, and according to any of the alternative embodiments described in conjunction with FIGS. 1-7B, will now be described. In an initial method step, a pair of panels, or substrates, for example substrates 11, 12, are formed according to methods well known in the art. Formation of one or both of the substrates may include a step of coating one or both major surfaces of the substrate. In assemblies according to embodiments of the invention, the major surface of one of the substrates, which will face a major surface of the other substrate in the photovoltaic assembly, for example, second surface 122 of first substrate 11, is coated with a photovoltaic coating, according to methods known to those skilled in the art. The initial substrate formation step may further include a step of forming at least one opening through at least one of the substrates, preferably, the substrate which does not include the coating.

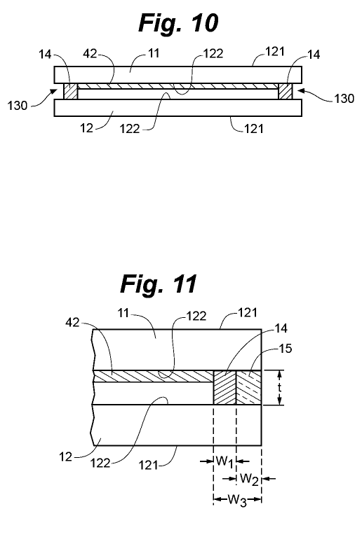

According to preferred methods, either prior to, during, or following substrate formation, a first seal 14 is applied to second surface 122 of either first or second substrate 11, 12. In embodiments which include a spacer, the spacer may be adhered to the second surface 122 sequentially or simultaneously with the first seal 14. According to an exemplary method, first seal 14 is sandwiched between the facing surfaces of the pair of substrates to join the substrates together along their peripheries while maintaining an airspace between the facing surfaces. Following “sandwiching”, according to some preferred methods of the present invention, pressure is applied to the assembly to affix first seal 14 to the facing surfaces of the pair of substrates in order to form a partial coherent assembly. Referring to FIG. 10, an assembly 10 is shown with first seal 14 in place and recessed from the peripheral edges of substrates 11, 12, defining a peripheral channel 130. Second seal 15 is deposited or applied into peripheral channel 130 and over first seal 14. If the material forming second seal 15 requires curing, it will be allowed to cure after being deposited or after the assembly pressure has been applied to form a partially coherent assembly.

According to other embodiments of preferred methods, either prior to, during, or following substrate formation, first seal 14 and second seal 15 are deposited either serially or simultaneously to second surface 122 of either first or second substrate 11, 12. In embodiments which include a spacer, the spacer may be adhered either serially or simultaneously with the first seal 14 and second seal 15. According to an exemplary method, first and second seals 14, 15, and optionally the spacer, are sandwiched between the facing surfaces of the pair of substrates to join the substrates together along their peripheries while maintaining an airspace between the facing surfaces. Following “sandwiching”, according to some preferred methods of the present invention, pressure is applied to affix seal system 13 to the facing surfaces of the pair of substrates in order to form a coherent assembly, for example, assembly 10, which still includes an airspace, such as airspace 200.

According to a further embodiment of preferred methods according to the invention, first and second substrates 11, 12 are provided with first substrate 11, being formed of a transparent or light transmitting material and each of the first and second substrates having first and second major surface 121, 122, each second surface having a central region 103 and a periphery 105 and the second surfaces facing one another and spaced apart from one another such that their peripheries are at least partially overlapping and in some embodiments their peripheries or edges are aligned. Also first substrate has a photovoltaic coating disposed over at least a portion of second major surface 122, for example over central region 103 or over both central region 103 and periphery 105. A seal system 13 is also provided and includes first seal 14 and second seal 15. The step of providing seal system 13 may further comprise applying steps where first seal 14 is first applied or where first and second seals 14, 15 are applied serially or simultaneously, prior to forming the assembly. The provided components are assembled to form assembly 10. The assembly step includes, in some embodiments, applying pressure to the assembly so as to affix seal system 13 or first seal 14 to substrates 11, 12. If first seal 14 is initially applied without second seal 15, second seal 15 is applied over first seal 14 and otherwise deposited into peripheral channel 130.

In some of the various embodiments of the method of the invention, the method may further comprise one or more of the following additional steps: providing a desiccant; depositing or dispensing a desiccant in airspace 200; routing lead wires out from the from airspace 200; and forming an opening 18 through the second substrate; providing a pre-formed opening or grommet; routing lead wires out from airspace 200 through opening 18 and/or through a pre-formed opening or grommet. The steps of providing desiccant or depositing or dispensing desiccant in airspace 200 may be carried out prior to or after forming the assembly or a partially coherent assembly depending upon the type of desiccant or form of the desiccant material provided, e.g., in wafer, sheet form or “free-floating” granules. Referring to FIG. 11, first seal 14 and second seal 15 are shown having respective widths w₁ and w₂ and seal system 13 has an overall width w₃, with w₃ representing the combined width of w₁ and w₂. In embodiments of the present invention, width w₃ may range between approximately 0.2 inch and approximately 1.5 inches. According to preferred embodiments of the present invention, width w₃ is preferably between approximately 0.2 inch and approximately 1 inch.

In either of the above described embodiments of the method according to the invention, pressure may be applied to assembly 10 manually or with pressing devices known to those skilled in the art. During the pressing step, pressure is applied to press the assembly to a nominal thickness or so that seal system 13 or first seal 14 has a thickness t.

After substrates 11, 12 are affixed to seal system 13, according to those embodiments that include one or more openings, for example, openings 18 in substrate 12 (FIG. 3) or seal opening 19 in seal system 13, the opening(s) may be used to perform secondary operations related to an airspace, for example, airspace 200. According to a preferred embodiment, which includes a photovoltaic coating, such as coating 700 described in conjunction with FIG. 7A, the secondary operations, that may be performed via opening(s) 18, 19 include dispensing a desiccant into airspace 200 and coupling lead wires to bus bar 706 (FIG. 7A). According to some embodiments, the coupled lead wires are routed out from airspace 200 through opening(s) 18, but according to alternate embodiments, the coupled lead wires are routed out through seal system 13 or through seal openings 19 in seal system 13, for example, as previously described in conjunction with FIG. 7B, in which case, the wires may have been previously coupled to coating 42, 42′ or bus bar 706, prior to affixing one or both of substrates 11, 12 to seal system 13. A diameter of the opening(s) 18, 19 may be between approximately ¼ inch and approximately 1 inch in order to accommodate these secondary operations. In a further method step, for these embodiments, one or more openings are sealed off with a potting material. If substrate 12 bears a photovoltaic coating, along an inner or second surface 122 thereof, and lead wires extend through the one or more openings, then the potting material is applied around the lead wires to seal off the opening. Examples of suitable potting materials include, without limitation, silyl-containing polyacrylate polymer, XMAP™ polymer, polyurethane, epoxy, polyisobutylene, and any low MVTR material; according to some embodiments, the same materials which forms first seal 14 or second seal may be used for the potting material.

All of the embodiments of the invention may optionally be provided with or without a spacer. Spacers may be formed of metal and/or non-metal material, such as metal or plastic tubing, for example, and may be provided in a variety of cross sectional configurations. The spacers typically includes two generally-opposed lateral surfaces, which are adapted to be bonded to inner peripheral surfaces of the spaced apart panes. Examples of spacer designs are provided in U.S. Pat. Nos. 5,439,716, 5,377,473, 5,679,419, 5,705,010 and 5,714,214, the entire teachings of each of which are incorporated herein by reference. In addition to generally tubular metal or plastic spacers, any suitable spacer may be utilized, for example spacers based on warm edge technology, e.g. polymeric foam or thermoset polymers (ethylene-propylene-diene monomer) or thermoplastic polymers. Examples of commercially available polymer based or warm edge spacers include Kodimelt TPS from Adco Products and Kommerling, and Super Spacer® products from Edgetech I.G. Inc. (Cambridge, Ohio, USA). The use of spacers or other spacer designs are contemplated as within the scope of the invention. Choice of spacers and their shape or design depends upon material compatibility, adhesion, and other performance parameters, e.g., permeability, and the like.

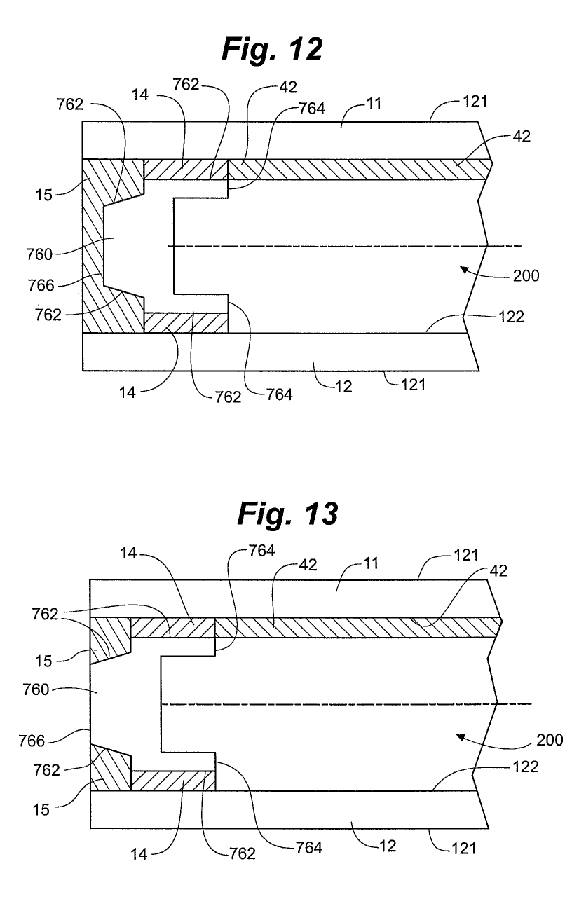

FIGS. 12 and 13 are section views through a photovoltaic device, according to various embodiments of the present invention. FIGS. 12 and 13 illustrate one example of a spacer 760 having lateral surfaces 762, a front surface 764 and a rear surface 766. The front surface 764 is oriented toward and faces the inside of the photovoltaic device while the rear surface 766 is oriented toward and faces the periphery of the photovoltaic device. The first seal 14 bonds at least a portion of the lateral surfaces 762 to the second surface 122 of the first and second substrate 11, 12. The portion of the lateral surface 762 which is bonded by the first seal 14 is the portion adjacent to the front surface 764 of the spacer 760. The second seal 15 may also bond at least a portion of the lateral surface 762 of the spacer 760 to the second surfaces 122 of the first and second substrate 11, 12, as shown in FIGS. 12 and 13. The portion of the lateral surface 762 which is bonded by the second seal 15 is the portion adjacent to the rear surface 766.

In the embodiment shown in FIG. 12, the second seal 15 extends across the rear surface 766 of the spacer from the first substrate 11 to the second substrate 12. Alternatively, the second seal 15 may only be located adjacent to the portion of the lateral surface 762 which is adjacent to the rear surface 766 without extending over the rear surface 766, as is shown in the embodiment depicted in FIG. 13. In another alternative embodiment, the second seal 15 be located adjacent to the lateral surface 762 and may extend around the rear surface 766 to partially cover the rear surface without extending from the first to the second substrate 11, 12. In yet another embodiment, the second seal may not be located adjacent to the lateral surface 762 at all and the first seal may extend the entire length of the lateral surface 762. In such embodiments, the second seal may only be located adjacent to the rear surface 766. the second seal 15 may cover only a portion of the rear surface 766 or may extend from the first to the second substrate 11, 12.

In the embodiments shown in FIGS. 12 and 13 and described above, the photovoltaic coating extends along the second surface 122 of the first substrate 11 and stops at approximately the location of the spacer 760. It is also contemplated that the photovoltaic coating 42 may extend into the space between the spacer 760 and the second surface 122, either partially or completely, such as is shown in FIGS. 5 and 6. In such embodiments, the spacer 760 may be bonded to the first and second substrate 11, 12 according to the various embodiments described above, but with the photovoltaic coating 42 being located between the first seal 14 (or between the first and second seals 14, 15) and the first substrate 122. In this way, the spacer is bonded to the photovoltaic coating 42 by the first seal 14 (or by the first and second seals 14, 15), depending on how far the photovoltaic coating 122 extends, and the spacer 760 does not directly contact the photovoltaic coating 42.

In the foregoing detailed description, the invention has been described with reference to specific embodiments. However, it may be appreciated that various modifications and changes can be made without departing from the scope of the invention.

What is claimed:

1. A photovoltaic assembly, comprising:
a first substrate, being formed of a transparent or light transmitting material, and a second substrate, each of the first and second substrates having first and second major surfaces, each second surface having a central region and a periphery and the second surfaces facing and spaced apart from one another;
a photovoltaic coating disposed over at least the central region of the second surface of the first substrate or the second substrate; and
a seal system comprising a first seal and a second seal, the seal system disposed between the first and second substrates and joining the first and second substrates to one another, along their peripheries, the seal system enclosing an airspace that extends between the second surfaces of the first and second substrates and along the central regions thereof, the second seal comprising a composition comprising:
a silyl containing polyacrylate polymer;
an alkoxysilane; and
a catalyst.

2. The assembly of claim 1, wherein the silyl containing polyacrylate polymer comprises a silyl terminated polyacrylate polymer.

3. The assembly of claim 1, wherein the second seal comprises a XMAP™ polymer.

4. The assembly of claim 1, wherein the first seal is formed of an extrudable material that results in a moisture vapor transmission rate therethrough, which does not exceed approximately 10 g mm/m²/day.

5. The assembly of claim 1 wherein the first seal is formed of a desiccant-free polymeric material.

6. The assembly of claim 1 wherein the first seal comprises a thermoplastic material and a desiccant.

7. The assembly of claim 1, wherein the first seal is comprised of a butyl sealant material.

8. The assembly of claim 1, wherein the coating is disposed over both the central region and the periphery of the second surface of the substrate over which the photovoltaic coating is disposed.

9. The assembly of claim 1, wherein the seal system extends over the periphery of the substrates.

10. The assembly of claim 9, wherein the seal system further extends over an edge portion of the coating, the edge portion being located adjacent to the periphery of the second surface the substrate over which the photovoltaic coating is disposed.

11. The assembly of claim 1, further comprising at least one opening extending through either the seal system or through the substrate opposite the substrate over which the photovoltaic coating is disposed, from the first surface to the second surface thereof.

12. The assembly of claim 11, further comprising a bus bar affixed to the photovoltaic coating and a lead wire coupled to the bus bar and extending through the at least one opening or between the seal system and second surface of the substrate over which the photovoltaic coating is disposed.

13. The assembly of claim 11, further comprising a potting material sealing the at least one opening.

14. The assembly of claim 1, further comprising a desiccant material disposed within the air space.

15. The assembly of claim 1, further comprising one or more support members, the one or more support members being disposed within the airspace.

16. The assembly of claim 1, further comprising one or more openings extending through the substrate opposite the substrate over which the photovoltaic coating is disposed, from the first surface to the second surface thereof, the openings having a periphery, and a seal member at least partially bordering or surrounding the periphery of the one or more openings.

17. A photovoltaic assembly, comprising:
a first substrate, being formed of a transparent or light transmitting material, and a second substrate, each of the first and second substrates having first and second major surfaces, each second surface having a central region and a periphery and the second surfaces facing and spaced apart from one another;
a photovoltaic coating disposed over at least the central region of the second surface of the first substrate or the second substrate;
a seal system comprising a first seal and a second seal, the seal system disposed between the first and second substrates and joining the first and second substrates to one another, along their peripheries, the seal system enclosing an airspace that extends between the second surfaces of the first and second substrates and along the central regions thereof, the second seal comprising a composition comprising:
a silyl-terminated polyacrylate polymer with an average of at least 1.2 alkoxysilyl chain terminations per molecule of the average formula
SiR¹ₓ(OR)₃₋ₓ
wherein R is methyl, ethyl, n-propyl, or isopropyl, R¹ is methyl or ethyl, and x is 0 or 1;
an alkoxysilane; and
a catalyst.

18. A photovoltaic assembly, comprising:
a first substrate, being formed of a transparent or light transmitting material, and a second substrate, each of the first and second substrates having first and second major surfaces, each second surface having a central region and a periphery and the second surfaces facing and spaced apart from one another;
a photovoltaic coating disposed over at least the central region of the second surface of the first substrate or the second substrate;
a seal system comprising a first seal and a second seal, the seal system disposed between the first and second substrates and joining the first and second substrates to one another, along their peripheries, the seal system enclosing an airspace that extends between the second surfaces of the first and second substrates and along the central regions thereof, the second seal comprising a composition comprising:
a silyl containing polyacrylate polymer;
an alkoxysilane; and
a catalyst;
at least one opening extending through either the seal system or through the substrate opposite the substrate over which the photovoltaic coating is disposed, from the first surface to the second surface thereof; and
potting material sealing the at least one opening, wherein the potting material comprises a silyl containing polyacrylate polymer.

19. A method for making a photovoltaic assembly, the method comprising:
forming a first substrate and a second substrate, the first and second substrates having first and second major surfaces, each of the second surfaces having a central region and a periphery, and at least the first substrate being transparent;
forming a photovoltaic coating over at least the central region of the second surface of the first substrate or the second substrate;
providing a seal system comprising a first seal and a second seal, the second seal comprising a composition comprising:
a silyl containing polyacrylate polymer;
an alkoxysilane; and
a catalyst;
applying the first seal to the periphery of at least one of the substrates;
bringing the first and second substrates together in opposed relationship with the first seal disposed along the peripheries thereof, such that an airspace is formed between the second surfaces and along the central regions thereof; and
applying pressure to the assembly to join the first and second substrates together such that the airspace is maintained between the first and second substrates.

20. The method of claim 19, wherein the silyl containing polyacrylate polymer comprises a silyl terminated polyacrylate polymer.

21. The method of claim 19, wherein the second seal comprises a XMAP™ polymer.

22. The method of claims 19, further comprising applying a second seal over the first seal.

23. The method of claim 19, wherein the applying step further comprises depositing the first and second seals serially or simultaneously, prior to bringing the first and second substrates together.

24. The method of claim 19, further comprising forming at least one opening through the seal system or through the substrate opposite the substrate over which the photovoltaic coating is disposed, from the first surface to the second surface thereof.

25. The method of claim 24, further comprising sealing the opening.

26. The method of claim 24, wherein the photovoltaic coating includes bus bars affixed thereto and lead wires coupled to the bus bars of the photovoltaic coating, the method further comprising extending said lead wires through the at least one opening.

27. The method of claim 19, wherein the photovoltaic coating is formed over both the central region and the periphery of the second surface of the substrate over which the photovoltaic coating is disposed.

28. The method of claim 19, further comprising providing at least one support member and/or a desiccant in the airspace.

29. The method of claim 19, wherein the first seal is formed of materials that result in a moisture vapor transmission rate therethrough, which does not exceed approximately 10 g mm/m²/day.

30. The method of claim 19, wherein the first seal is comprised of a butyl sealant material.

31. A method for making a photovoltaic assembly, the method comprising:
providing a first substrate and a second substrate, the first and second substrates having first and second major surfaces, each of the second surfaces having a central region and a periphery, at least the first substrate being transparent, and at least one of the substrates bearing a photovoltaic coating disposed over at least the central region of the second major surface;
providing a seal system comprising a first seal and a second seal disposed along the periphery of at least one of the substrates, the second seal comprising a composition comprising:
a silyl containing polyacrylate polymer;
an alkoxysilane; and
a catalyst;
bringing the first and second substrates together in opposed relationship with the first seal disposed along the peripheries thereof, such that an airspace is formed between the second surfaces and along the central regions thereof; and
applying pressure to the assembly to join the first and second substrates together such that the airspace is maintained between the first and second substrates.

32. The method of claim 31, wherein the silyl containing polyacrylate polymer comprises a silyl terminated polyacrylate polymer.

33. The method of claim 31, wherein the second seal comprises a XMAP™ polymer.

34. The assembly of claim 1, further comprising a spacer disposed between the first and second substrates and adhered to the first and second substrate along a periphery the first and second substrates by at least the first seal.
